(19) United States
(12) Patent Application Publication
(10) Pub. No.: US 2014/0266485 A1
(43) Pub. Date: Sep. 18, 2014

(54) RESONATOR, OSCILLATOR, ELECTRONIC APPARATUS, AND MOVING OBJECT

(71) Applicant: SEIKO EPSON CORPORATION, Tokyo (JP)

(72) Inventor: Akinori YAMADA, Suwa-shi (JP)

(73) Assignee: SEIKO EPSON CORPORATION, Tokyo (JP)

(21) Appl. No.: 14/202,299

(22) Filed: Mar. 10, 2014

(30) Foreign Application Priority Data
Mar. 14, 2013 (JP) 2013-052488

(51) Int. Cl. H01L 41/113; H03B 5/32

(52) U.S. Cl. CPC H01L 41/113; H03B 5/32
USPC 331/158; 310/361; 310/318

(57) ABSTRACT

A resonator includes a resonator element, which includes a quartz crystal substrate formed of crystal, and a package in which the resonator element is housed. The quartz crystal substrate includes a base portion and two vibrating arms that are aligned in the X-axis direction of the crystal and extend from the base portion in the +Y′-axis direction (or the −Y′-axis direction) of the quartz crystal. The principal surface of the base portion on the −Z′-axis side (+Z′-axis side when the vibrating arms extend in the −Y′-axis direction) in the quartz crystal is fixed to the package.

### BACKGROUND

1. Technical Field

The present invention relates to a resonator, an oscillator, an electronic apparatus, and a moving object.

2. Related Art

As a resonator, a so-called 2-leg tuning fork type quartz crystal resonator is known (for example, refer to JP-A-59-171208). In such a resonator, generally, a vibrating reed is housed in a package.

For example, the resonator element in the resonator disclosed in JP-A-59-171208 includes a base portion and two vibrating arms extending in parallel from the base portion, and the two vibrating arms are made to bend and vibrate in a direction (in-plane direction) moving closer to or away from each other.

The aforementioned base portion and vibrating arms are integrally formed of crystal. Crystal has an X axis (electrical axis), a Y axis (mechanical axis), and a Z axis (optical axis), which are perpendicular to each other, as crystal axes.

In the resonator disclosed in JP-A-59-171208, each vibrating arm extends from the base portion in a +Y′-axis direction, and a surface of the base portion on the +Z′-axis side is fixed to the package. Here, the Y′ and Z′ axes are axes set by rotating the Y and Z axes around the X axis by a predetermined angle.

In such a known resonator, however, there has been a problem that vibration leakage to the package from the resonator element is large.

### SUMMARY

An advantage of some aspects of the invention is to provide a resonator capable of reducing the vibration leakage to a package from a resonator element and to provide an oscillator with excellent reliability that includes the resonator, an electronic apparatus, and a moving object.

The invention can be implemented as the following application examples.

### APPLICATION EXAMPLE 1

This application example is directed to a resonator including: a resonator element including a vibrating body formed of crystal; and a package in which the resonator element is housed. In a Cartesian coordinate system having an X axis as an electrical axis, a Y axis as a mechanical axis, and a Z axis as an optical axis of the crystal, assuming that an axis obtained by inclining the Z axis so that a +Z side rotates in a −Y direction of the Y axis with the X axis as a rotation axis is a Z′ axis and an axis obtained by inclining the Y axis so that a +Y side rotates in a +Z direction of the Z axis with the X axis as a rotation axis is a Y′ axis, the vibrating body includes a base portion and two vibrating arms that are aligned along the X-axis direction and extend along the Y′ axis from the base portion in plan view. A principal surface of the base portion crossing the Z′ axis is fixed to the package. A polarity of the Y′ axis in the extending direction of the vibrating arms is different from a polarity of the Z′ axis that is in a direction in which the principal surface fixed to the package faces.

According to this resonator, it is possible to reduce the vibration leakage to the package from the resonator element.

### APPLICATION EXAMPLE 2

This application example is directed to the resonator according to the application example described above, wherein each of the vibrating arms extends in a positive direction of the Y′ axis, and the principal surface of the base portion fixed to the package faces a negative side of the Z′ axis.

According to this resonator, it is possible to reduce the vibration leakage to the package from the resonator element.

### APPLICATION EXAMPLE 3

This application example is directed to the resonator according to the application example described above, wherein each of the vibrating arms extends in a negative direction of the Y′ axis, and the principal surface of the base portion fixed to the package faces a positive side of the Z′ axis.

According to this resonator, it is possible to reduce the vibration leakage to the package from the resonator element.

### APPLICATION EXAMPLE 4

This application example is directed to the resonator according to the application example described above, wherein the base portion includes a main body connected to the vibrating arms, a fixed portion fixed to the package, and a connecting portion that connects the main body and the fixed portion to each other.

According to this configuration, it is possible to reduce the vibration leakage to the package from the resonator element effectively.

### APPLICATION EXAMPLE 5

This application example is directed to the resonator according to the application example described above, wherein the connecting portion extends from the main body to the vibrating arm side between the two vibrating arms.

According to this configuration, the connecting portion can be disposed between the two vibrating arms. Therefore, it is possible to reduce the size of the resonator element and as a result, it is possible to reduce the size of the resonator.

### APPLICATION EXAMPLE 6

This application example is directed to the resonator according to the application example described above, wherein the fixed portion is disposed between the two vibrating arms.

According to this configuration, it is possible to reduce the size of the resonator element effectively.

### APPLICATION EXAMPLE 7

This application example is directed to the resonator according to the application example described above, wherein the fixed portion is disposed on an opposite side to the main body with respect to the two vibrating arms.

According to this configuration, it is possible to reduce the vibration leakage to the package from the resonator element more effectively.

### APPLICATION EXAMPLE 8

This application example is directed to the resonator according to the application example described above, wherein the connecting portion includes a connection portion extending from the main body to an opposite side to the two vibrating arms.

According to this configuration, it is possible to reduce the vibration leakage to the package from the resonator element effectively.

### APPLICATION EXAMPLE 9

This application example is directed to the resonator according to the application example described above, wherein the fixed portion includes two island portions disposed so as to be spaced apart from each other along the X-axis direction, the two vibrating arms are disposed between the two island portions, and the connecting portion includes two branch portions that are branched from the connection portion and are connected to the two island portions.

According to this configuration, it is possible to reduce the vibration leakage to the package from the resonator element more effectively.

### APPLICATION EXAMPLE 10

This application example is directed to the resonator according to the application example described above, wherein the fixed portion extends from the connecting portion along a positive direction of the X axis or a negative direction of the X axis.

According to this configuration, it is possible to reduce the vibration leakage to the package from the resonator element more effectively.

### APPLICATION EXAMPLE 11

This application example is directed to the resonator according to the application example described above, wherein the base portion includes a width-decreasing portion, in which a length in the X-axis direction gradually decreases as a distance from each of the vibrating arms increases, in a portion on an opposite side to the two vibrating arms.

According to this configuration, it is possible to reduce the vibration leakage to the package from the resonator element effectively.

### APPLICATION EXAMPLE 12

This application example is directed to an oscillator including: the resonator according to the application example described above; and an oscillation circuit electrically connected to the resonator element.

According to this configuration, it is possible to provide an oscillator having excellent reliability.

### APPLICATION EXAMPLE 13

This application example is directed to an electronic apparatus including the resonator according to the application example described above.

According to this configuration, it is possible to provide an electronic apparatus having excellent reliability.

### APPLICATION EXAMPLE 14

This application example is directed to a moving object including the resonator according to the application example described above.

According to this configuration, it is possible to provide a moving object having excellent reliability.

### BRIEF DESCRIPTION OF THE DRAWINGS

The invention will be described with reference to the accompanying drawings, wherein like numbers reference like elements.

FIG. 1 is a plan view showing a resonator according to a first embodiment of the invention.

FIG. 2 is a cross-sectional view taken along the A-A line of FIG. 1.

FIG. 3 is a cross-sectional view of a resonator element provided in the resonator shown in FIG. 1 (cross-sectional view taken along the B-B line of FIG. 1).

FIG. 4 is a diagram for explaining a resonator element used in the analysis of the relationship between the extending direction of the vibrating arm and the fixed surface of the resonator element and vibration leakage.

FIG. 5 is a plan view showing a resonator according to a second embodiment of the invention.

FIG. 6 is a plan view showing a resonator according to a third embodiment of the invention.

FIGS. 7A and 7B are diagrams for explaining a base portion of a resonator element provided in the resonator shown in FIG. 6.

FIG. 8 is a diagram for explaining a vibrating arm used in the simulation to examine the relationship between the hammerhead occupancy of the vibrating arm and the low R1 index.

FIG. 9 is a diagram for explaining the width (effective width a) of a plate-shaped vibrating arm having the same Q value and natural frequency as the vibrating arm shown in FIG. 8.

FIGS. 10A and 10B are graphs showing the relationship between the hammerhead occupancy and the low R1 index.

FIG. 11 is a plan view showing a resonator according to a fourth embodiment of the invention.

FIG. 12 is a plan view showing a resonator according to a fifth embodiment of the invention.

FIG. 13 is a cross-sectional view showing an example of an oscillator according to an embodiment of the invention.

FIG. 14 is a perspective view showing the configuration of a mobile (or notebook) personal computer as an electronic apparatus including the resonator according to the embodiment of the invention.

FIG. 15 is a perspective view showing the configuration of a mobile phone (PHS is also included) as an electronic apparatus including the resonator according to the embodiment of the invention.

FIG. 16 is a perspective view showing the configuration of a digital still camera as an electronic apparatus including the resonator according to the embodiment of the invention.

FIG. 17 is a perspective view showing the configuration of a moving object (vehicle) as an electronic apparatus including the resonator according to the embodiment of the invention.

### DESCRIPTION OF EXEMPLARY EMBODIMENTS

Hereinafter, a resonator, an oscillator, an electronic apparatus, and a moving object according to the invention will be described in detail by way of preferred embodiments shown in the diagrams.

First, the resonator according to the invention will be described.

### First Embodiment

FIG. 1 is a plan view showing a resonator according to a first embodiment of the invention, FIG. 2 is a cross-sectional view taken along the A-A line of FIG. 1, and FIG. 3 is a cross-sectional view of a resonator element provided in the resonator shown in FIG. 1 (cross-sectional view taken along the B-B line of FIG. 1). In addition, FIG. 4 is a diagram for explaining a resonator element used in the analysis of the relationship between the extending direction of the vibrating arm and the fixed surface of the resonator element and vibration leakage.

In addition, in FIGS. 1 to 3, X, Y′, and Z′ axes are shown as three axes perpendicular to each other. In FIG. 4, X, Y, and Z axes are shown as three axes perpendicular to each other. It is assumed that the distal side of each arrow is “+ (positive)” and the proximal side is “− (negative)”. In addition, it is assumed that a direction parallel to the X axis is an “X-axis direction” a direction parallel to the Y axis is a “Y-axis direction”, a direction parallel to the Z axis direction is a “Z-axis direction”, a direction parallel to the Y′ axis is a “Y′-axis direction”, and a direction parallel to the Z′ axis direction is a “Z′-axis direction”. In addition, the +Z′ side (upper side in FIG. 2) is also called “top”, and −Z′ side (lower side in FIG. 2) is also called “bottom”.

In addition, the X, Y, and Z axes shown in FIG. 4 correspond to an X axis (electrical axis), a Y axis (mechanical axis), and a Z axis (optical axis) of the quartz crystal that forms a quartz crystal substrate 3 to be described later, respectively. The X axis shown in FIGS. 1 to 3 matches the X axis shown in FIG. 4, and the Y′ and Z′ axes shown in FIGS. 1 to 3 are axes set by rotating the Y and Z axes shown in FIG. 4 around the X axis by a predetermined angle (for example, less than 15°) from the +Y-axis side to the +Z-axis side. In addition, the Y′ and Z′ axes may match the Y and Z axes, respectively (that is, the predetermined angle may be 0°).

### 1. Resonator

A resonator 1 shown in FIGS. 1 and 2 includes a resonator element 2 and a package 9 in which the resonator element 2 is housed. Hereinafter, the resonator element 2 and the package 9 will be described in detail one by one.

### Resonator Element

As shown in FIGS. 1 to 3, the resonator element 2 of the present embodiment includes the quartz crystal substrate 3 (vibrating body) and first and second driving electrodes 84 and 85 formed on the quartz crystal substrate 3. In addition, in FIGS. 1 and 2, the first and second driving electrodes 84 and 85 are not shown for convenience of explanation.

The quartz crystal substrate 3 is formed of crystal. The quartz crystal substrate 3 is a quartz crystal substrate having the Z′ axis of the crystal as the thickness direction. Here, the top surface of the quartz crystal substrate 3 is a +Z′ surface of the crystal, and the bottom surface of the quartz crystal substrate 3 is a −Z′ surface of the crystal.

As shown in FIG. 1, the quartz crystal substrate 3 includes a base portion 4 and a pair of (two) vibrating arms 5 and 6 extending from the base portion 4.

The base portion 4 has a plate shape that spreads on the XY′ plane, which is a plane parallel to the X and Y′ axes, and has the Z′-axis direction as the thickness direction. Here, the top surface of the base portion 4 is the +Z′ surface of the crystal, and the bottom surface of the base portion 4 is the −Z′ surface of the crystal.

In the present embodiment, the base portion 4 includes a main body 41 connected to each of the vibrating arms 5 and 6, fixed portions 42 and 43 fixed to the package 9, and a connecting portion 44 that connects the main body 41 and the fixed portions 42 and 43 to each other. Therefore, it is possible to reduce the vibration leakage to the package from the resonator element effectively.

Here, the fixed portions 42 and 43 are island portions spaced apart from each other in the X-axis direction so that a pair of vibrating arms 5 and 6 are interposed therebetween.

The connecting portion 44 includes a connection portion 441 extending in the −Y′-axis direction from the main body 41 and branch portions 442 and 443 (connection arms) branched from the connection portion 441 so as to extend in the +X-axis direction and −X-axis direction.

The connection portion 441 extends from the main body 41 to the opposite side of the two vibrating arms 5 and 6.

The two branch portions 442 and 443 are branched from the connection portion 441 and are connected to the two fixed portions 42 and 43.

The fixed portions 42 and 43 extend in the +Y′-axis direction from the distal ends of the branch portions 442 and 443. In addition, the bottom surfaces 421 and 431 of the fixed portions 42 and 43 are the surface of the crystal. The bottom surfaces 421 and 431 are fixed to the package 9 as will be described in detail later.

In addition, the two vibrating arms 5 and 6 are disposed between the two fixed portions 42 and 43 (island portions).

According to the base portion 4 including the main body 41, the fixed portions 42 and 43, and the connecting portion 44, it is possible to reduce the vibration leakage to the package 9 from the resonator element 2 effectively.

The vibrating arms 5 and 6 are aligned in the X-axis direction, and extend in the +Y′-axis direction from the base portion 4 so as to be parallel to each other. Each of the vibrating arms 5 and 6 has a longitudinal shape. The base end (end on the base portion 4 side) of each of the vibrating arms 5 and 6 is a fixed end, and the distal end (end on the opposite side to the base portion 4) is a free end. In addition, hammerheads 59 and 69 are provided at the distal ends of the vibrating arms 5 and 6. In addition, weight portions for frequency adjustment may be provided in the hammerheads 59 and 69.

As shown in FIG. 3, the vibrating arm 5 has a pair of principal surfaces 51 and 52, which are the XY′ plane, and a pair of side surfaces 53 and 54, which are the Y′Z′ plane and to which the pair of principal surfaces 51 and 52 are connected. In addition, the vibrating arm 5 has a bottomed groove 55 opened to the principal surface 51 and a bottomed groove 56 opened to the principal surface 52. The grooves 55 and 56 extend in the Y′-axis direction. The vibrating arm 5 has an approximately H-shaped cross-sectional shape in a portion in which the grooves 55 and 56 are formed.

As shown in FIG. 3, it is preferable that the grooves 55 and 56 be formed symmetrically with respect to the line segment 1, which bisects the thickness of the vibrating arm 5, on the cross-section. Therefore, since it is possible to suppress unnecessary vibration (specifically, oblique vibration having an out-of-plane component) of the vibrating arm 5, the vibrating arm 5 can be made to vibrate efficiently in the in-plane direction of the quartz crystal substrate 3.

Similar to the vibrating arm 5, the vibrating arm 6 has a pair of principal surfaces 61 and 62, which are the XY′ plane, and a pair of side surfaces 63 and 64, which are the Y′Z′ plane and to which the pair of principal surfaces 61 and 62 are connected. In addition, the vibrating arm 6 has a bottomed groove 65 opened to the principal surface 61 and a bottomed groove 66 opened to the principal surface 62.

A pair of first driving electrodes 84 and a pair of second driving electrodes 85 are formed in the vibrating arm 5. Specifically, one of the first driving electrodes 84 is formed on the inner surface of the groove 55, and the other first driving electrode 84 is formed on the inner surface of the groove 56. In addition, one of the second driving electrodes 85 is formed on the side surface 53, and the other second driving electrode 85 is formed on the side surface 54.

Similarly, a pair of first driving electrodes 84 and a pair of second driving electrodes 85 are formed in the vibrating arm 6. Specifically, one of the first driving electrodes 84 is formed on the side surface 63, and the other first driving electrode 84 is formed on the side surface 64. In addition, one of the second driving electrodes 85 is formed on the inner surface of the groove 65, and the other second driving electrode 85 is formed on the inner surface of the groove 66.

When an AC voltage is applied between the first and second driving electrodes 84 and 85, the vibrating arms 5 and 6 vibrate at a predetermined frequency in the in-plane direction (XY′ plane direction) so as to alternate being close to and away from each other.

Materials of the first and second driving electrodes 84 and 85 are not limited in particular. For example, it is possible to use metal materials, such as gold (Au), gold alloy, platinum (Pt), aluminum (Al), aluminum alloy, silver (Ag), silver alloy, chromium (Cr), chromium alloy, nickel (Ni), nickel alloy, copper (Cu), molybdenum (Mo), niobium (Nb), tungsten (W), iron (Fe), titanium (Ti), cobalt (Co), zinc (Zn), and zirconium (Zr), and conductive materials, such as indium tine oxide (ITO).

### Package

The package 9 includes a box-shaped base 91 having a recess 911, which is opened on the top surface, and a plate-shaped lid 92 bonded to the base 91 so as to close the opening of the recess 911. The package 9 has a storage space formed by closing the recess 911 with the lid 92, and the resonator element 2 is housed in the storage space in an airtight manner.

In addition, the storage space may be in a decompressed (preferably, vacuum) state, or inert gas, such as nitrogen, helium, and argon, may be filled in the storage space. In this case, the vibration characteristics of the resonator element 2 are improved.

Materials of the base 91 are not limited in particular, and various ceramics, such as aluminum oxide, can be used. In addition, although materials of the lid 92 are not limited in particular, it is preferable to use a member having a linear expansion coefficient similar to that of the material of the base 91. For example, when the above-described ceramic is used as a material of the base 91, it is preferable to use an alloy, such as Kovar. In addition, bonding of the base 91 and the lid 92 is not limited in particular. For example, the base 91 and the lid 92 may be bonded to each other through an adhesive or may be bonded to each other by seam welding or the like.

In addition, connecting terminals 951 and 961 are formed on the bottom surface of the recess 911 of the base 91. Although not shown, the first driving electrode 84 of the resonator element 2 is pulled out to the distal end of the fixed portion 42, and is electrically connected to the connecting terminal 951 through a conductive adhesive 11 in the portion. Similarly, although not shown, the second driving electrode 85 of the resonator element 2 is pulled out to the distal end of the fixed portion 43, and is electrically connected to the connecting terminal 961 through the conductive adhesive 11 at the distal end.

In addition, the connecting terminal 951 is electrically connected to an external terminal 953, which is formed on the bottom surface of the base 91, through a penetrating electrode 952 passing through the base 91, and the connecting terminal 961 is electrically connected to an external terminal 963, which is formed on the bottom surface of the base 91, through a penetrating electrode 962 passing through the base 91.

Materials of the connecting terminals 951 and 961, the penetrating electrodes 952 and 962, and the external terminals 953 and 963 are not limited in particular as long as the materials are electrically conductive. For example, the connecting terminals 951 and 961, the penetrating electrodes 952 and 962, and the external terminals 953 and 963 may be formed of metal coat that is formed by laminating each coat, such as Ni (nickel), Au (gold), Ag (silver), or Cu (copper), on a metallized layer (base layer), such as Cr (chromium) or W (tungsten).

The resonator element 2 housed in the package 9 is fixed to the bottom surface of the recess 911 through the conductive adhesive 11, which is formed by mixing a conductive filler in an epoxy-based or acrylic resin, for example, at the distal ends of the bottom surfaces 421 and 431 of the fixed portions 42 and 43 (refer to FIG. 2).

That is, in the resonator element 2 in which the vibrating arms 5 and 6 extend in the +Y′-axis direction, the principal surface of the base portion 4 on the −Z′-axis side of the crystal is fixed to the package 9. Therefore, it is possible to reduce the vibration leakage to the package 9 from the resonator element 2.

Hereinafter, the principle of such suppression of the vibration leakage will be described.

The present inventors conducted analysis of vibration leakage for a 2-leg tuning fork type resonator element 2X shown in FIG. 4.

The resonator element 2X includes a quartz crystal substrate 3X formed of a crystal Z plate.

The quartz crystal substrate 3X includes a base portion 4X, which has an approximately rectangular shape in plan view, and a pair of vibrating arms 5X and 6X extending in the +Y-axis direction from the base portion 4X.

Here, each of the vibrating arms 5X and 6X has a thickness of 130 μm, a width of 324 μm, and a length of 1240 μm, and the length of the base portion 4X in the Y-axis direction is 1760 μm.

In addition, weight portions 59X and 69X that are formed of gold and have a thickness of 2 μm are provided at the distal ends of the vibrating arms 5X and 6X.

In addition, the bottom surface of the base portion 4X is a −Z surface (surface on the −Z-axis side), and the top surface of the base portion 4X is a +Z surface (surface on the +Z-axis side). In this analysis, two portions, which are spaced apart from each other, at the opposite end to the vibrating arms 5X and 6X on one surface of the base portion 4X are set as holding portions 71 and 72. In addition, in FIG. 4, a case is shown in which the holding portions 71 and 72 are set on the top surface (+Z surface) of the base portion 4X.

In addition, the vibration frequency of the resonator element 2X is 149 kHz.

In addition, this analysis is based on a calculation that the elastic energy reaching the holding portions 71 and 72 does not return to the resonator element 2X while being transmitted to the semi-infinite medium provided virtually on the surface of the holding portions 71 and 72. This energy transmitted to the semi-infinite medium never contributes to bending and vibration in the resonator element 2X. That is, the loss of the energy transmitted to the semi-infinite medium is a loss due to vibration leakage. In addition, the Q value when only this loss due to vibration leakage is considered is defined as Qₗₑₐₖ (Qₗₑₐₖ decreases as vibration leakage increases).

The aforementioned calculation was performed for each of a case where the holding portions 71 and 72 (fixed surfaces) were set on the +Z surface of the base portion 4X and a case where the holding portions 71 and 72 (fixed surfaces) were set on the −Z surface of the base portion 4X when the vibrating arms 5X and 6X extended in the +Y-axis direction and when the vibrating arms 5X and 6X extended in the −Y-axis direction.

The result is shown in Table 1.

TABLE 1

| Extending direction | | |
|---|---|---|
| of vibrating arm | Fixed surface | Qₗₑₐₖ |
| +Y-axis direction | +Z surface | 299,035 |
| | −Z surface | 443,942 |
| −Y-axis direction | +Z surface | 428,649 |
| | −Z surface | 284,505 |

As can be seen from Table 1, when the vibrating arms 5X and 6X extend in the +Y-axis direction, vibration leakage is smaller when the holding portions 71 and 72 are set on the −Z surface compared to when the holding portions 71 and 72 are set on the +Z surface.

In addition, when the vibrating arms 5X and 6X extend in the −Y-axis direction, vibration leakage is smaller when the holding portions 71 and 72 are set on the +Z surface compared to when the holding portions 71 and 72 are set on the −Z surface.

In addition, for a resonator element in which the extending direction of the vibrating arms 5X and 6X is a Y′-axis direction and the thickness direction of the base portion 4X is a Z′-axis direction, it is confirmed that the same result as in Table 1 is obtained.

Hereinafter, the reasons for such result shown in Table 1 will be described.

Stress in the crystal Z plate is expressed as in the following Expression (1).

$$[ \begin{matrix}{T}_{1} \\ {T}_{2} \\ {T}_{3} \\ {T}_{4} \\ {T}_{5} \\ {T}_{6}\end{matrix} ] = [ \begin{matrix}{c}_{11} & {c}_{12} & {c}_{13} & {c}_{14} & 0 & 0 \\ {c}_{12} & {c}_{11} & {c}_{13} & - {c}_{14} & 0 & 0 \\ {c}_{13} & {c}_{13} & {c}_{33} & 0 & 0 & 0 \\ {c}_{14} & - {c}_{14} & 0 & {c}_{44} & 0 & 0 \\ 0 & 0 & 0 & 0 & {c}_{44} & {c}_{14} \\ 0 & 0 & 0 & 0 & {c}_{14} & {c}_{66}\end{matrix} ] [ \begin{matrix}\frac{\partial {u}_{1}}{\partial {x}_{1}} \\ \frac{\partial {u}_{2}}{\partial {x}_{2}} \\ \frac{\partial {u}_{3}}{\partial {x}_{3}} \\ \frac{\partial {u}_{2}}{\partial {x}_{3}} + \frac{\partial {u}_{3}}{\partial {x}_{2}} \\ \frac{\partial {u}_{1}}{\partial {x}_{3}} + \frac{\partial {u}_{3}}{\partial {x}_{1}} \\ \frac{\partial {u}_{1}}{\partial {x}_{2}} + \frac{\partial {u}_{2}}{\partial {x}_{1}}\end{matrix} ] , \\ {c}_{66} = \frac{{c}_{11} - {c}_{12}}{2} \qquad ( 1 )$$

In the above Expression (1), for natural numbers I and J of 1 to 6, T_{I} is a “component of Cauchy stress tensor”, C_{IJ} is an “elastic stiffness constant of the crystal Z plate”, u₁ is a “component of a displacement vector in the X-axis (electrical axis) direction of the crystal”, u₂ is a “component of a displacement vector in the Y-axis (mechanical axis) direction of the crystal”, and u₃ is a “component of a displacement vector in the Z-axis (optical axis) direction of the crystal”. In addition, x₁ is the “coordinate in the X-axis (electrical axis) direction of the crystal”, x₂ is the “coordinate in the Y-axis (mechanical axis) direction of the crystal”, and x₃ is the “coordinate in the Z-axis (optical axis) direction of the crystal”. The following notation is based on the literature (B. A. Auld, “Acoustic Fields and Waves in Solids”, second edition, Krieger Publishing Company, 1990.).

In Expression (1) shown above, T₃, T₄, and T₅ are involved in the stress boundary conditions on the ±Z surfaces of the crystal Z plate. T₃, T₄, and T₅ are expressed as in the following Expression (2).

$$\begin{matrix}{T}_{3} = {c}_{13} ( \frac{\partial {u}_{1}}{\partial {x}_{1}} + \frac{\partial {u}_{2}}{\partial {x}_{2}} ) + {c}_{33} \frac{\partial {u}_{3}}{\partial {x}_{3}} \\ {T}_{4} = {c}_{14} ( \frac{\partial {u}_{1}}{\partial {x}_{1}} + \frac{\partial {u}_{2}}{\partial {x}_{2}} ) + {c}_{44} ( \frac{\partial {u}_{2}}{\partial {x}_{3}} + \frac{\partial {u}_{3}}{\partial {x}_{2}} ) \\ {T}_{5} = {c}_{44} ( \frac{\partial {u}_{1}}{\partial {x}_{3}} + \frac{\partial {u}_{3}}{\partial {x}_{1}} ) + {c}_{14} ( \frac{\partial {u}_{1}}{\partial {x}_{2}} + \frac{\partial {u}_{2}}{\partial {x}_{1}} )\end{matrix} \} \qquad ( 2 )$$

In the 2-leg tuning fork type resonator element 2X in which the vibrating arms 5X and 6X perform in-plane vibration, vibration occurring in the quartz crystal substrate 3X is approximately in-plane vibration. For this reason, it is possible to ignore the derivatives of the displacement components u₃ and x₃ in the above Expression (2). Therefore, the above Expression (2) can be simplified as the following Expression (3).

$${T}_{3} \approx {c}_{13} ( \frac{\partial {u}_{1}}{\partial {x}_{1}} + \frac{\partial {u}_{2}}{\partial {x}_{2}} ) , {T}_{4} \approx ( \frac{\partial {u}_{1}}{\partial {x}_{1}} + \frac{\partial {u}_{2}}{\partial {x}_{2}} ) , {T}_{5} \approx {c}_{14} ( \frac{\partial {u}_{1}}{\partial {x}_{2}} + \frac{\partial {u}_{2}}{\partial {x}_{1}} ) \qquad ( 3 )$$

In addition, by performing surface integral for a result obtained by analyzing the above Expression (3) for the fixed surface (surface on a side where the holding portions 71 and 72 are set) of the base portion 4X of the quartz crystal substrate 3X, stress |Re{T₃}|, |Re{T₄}|, and |Re{T₅}| in each holding portion is calculated as follows.

|Re{T₃}|≅1.45×10⁻⁷ [Pa]

|Re{T₄}|≅8.26×10⁻⁷ [Pa]

|Re{T₅}|≅0.69×10⁻⁷ [Pa]

In addition, although the stress in the analysis including the loss is complex numbers, only the real parts are used for |Re{T₃}|, |Re{T₄}|, and |Re{T₅}| so as to be able to be compared with each other.

From such result, it can be seen that a sufficiently good approximation of the stress in the holding portion of the quartz crystal substrate 3X using the crystal Z plate can be obtained if only T₄ is taken into consideration. That is, in order to calculate an approximate value of the stress in the holding portion of the quartz crystal substrate 3X using the crystal Z plate, it is sufficient to consider only the elastic stiffness constant c₁₄.

When rotating the crystal Z plate around the Y axis by 180° or when rotating the crystal Z plate around the Z axis by 180°, the sign of only the elastic stiffness constant c₁₄ is changed (from positive to negative or from negative to positive).

Therefore, when the vibrating arms 5X and 6X extend in the +Y-axis direction, assuming that Qₗₑₐₖ when holding the −Z-axis side surface of the base portion 4X of the resonator element 2X is Qₗₑₐₖ₋ and Qₗₑₐₖ when holding the +Z-axis side surface of the base portion 4X of the resonator element 2X is Qₗₑₐₖ₊, the difference ΔQₗₑₐₖ=Qₗₑₐₖ₋−Qₗₑₐₖ₊>0 is changed to ΔQₗₑₐₖ<0 due to 180° rotation around the Y axis or 180° rotation around the Z axis. That is, ΔQₗₑₐₖ>0 is satisfied when the vibrating arms 5X and 6X extend in the +Y-axis direction, while ΔQₗₑₐₖ<0 is satisfied when the vibrating arms 5X and 6X extend in the −Y-axis direction. Therefore, when the vibrating arms 5X and 6X extend in the −Y-axis direction, vibration leakage when holding the +Z-axis side surface is small.

In the 2-leg tuning fork type resonator element 2X in which the vibrating arms 5X and 6X extend in the Y-axis direction, vibration leakage can be reduced by offsetting the vibration (in-plane vibration) of the two vibrating arms 5X and 6X in the ±X-axis directions in the base portion 4X, but vibration leakage in the ±Y-axis directions necessarily remains on the −Y-axis direction side of the base portion 4X.

The vibration leakage in the ±Y-axis directions causes stress in the ±Y-axis directions on the fixed surface of the resonator element 2X. Such stress is equivalent to the above-described stress T₄ (stress in the Y-axis direction on the Z surface).

This stress T₄ is mainly due to the elastic stiffness constant c₁₄, and the sign of the elastic stiffness constant c₁₄ on the +Z surface and the sign of the elastic stiffness constant c₁₄ on the −Z surface are opposite signs.

Vibration that is actually obtained as a calculation result is natural vibration (including vibration leakage) from which a threshold value satisfying the principle of virtual work, which will be described later, is obtained. Therefore, ΔQₗₑₐₖ>0 was confirmed when the vibrating arms 5X and 6X extended in the +Y-axis direction. In addition, the above-described difference between the sign of the elastic stiffness constant c₁₄ on the +Z surface and the sign of the elastic stiffness constant c₁₄ on the −Z surface appears as a difference between the vibration leakage Qₗₑₐₖ₊ on the +Z surface and the vibration leakage Qₗₑₐₖ₋ on the −Z surface.

In addition, the Q value (Qₜₒₜₐₗ) of the resonator element is expressed as in the following Expression (4).

Qₜₒₜₐₗ⁻¹=Q_{TED}⁻¹+Q_{VED}⁻¹+Q_{Leak}⁻¹+Q_{Air}⁻¹ (4)

In the above Expression (4), Q_{TED} is a “Q value when only the thermoelastic loss is considered”, Q_{VED} is a “Q value when only the viscoelastic loss is considered”, Qₗₑₐₖ is a “Q value when only the vibration leakage is considered”, and Q_{Air} is a “Q value when only the air resistance (viscous resistance of air) is considered”.

In addition, the principle of virtual work is expressed as in the following Expression (5).

$$δ {\int }_{Ω} \frac{1}{2} {T}_{ij} {S}_{ij} d Ω - {( jω )}^{2} {\int }_{Ω} ρ {u}_{i} δ {u}_{i} d Ω + {\int }_{Γ} {T}_{ij} {n}_{j} δ {u}_{i} d Γ = 0 \qquad ( 5 )$$

In the above Expression (5), δ is a “variation”, ω is an “angular frequency”, j (not a suffix) is an imaginary unit, Tᵢⱼ (i=1 to 3, j=1 to 3) is a “component of Cauchy stress tensor”, Sᵢⱼ (i=1 to 3, j=1 to 3) is a “component of infinitesimal stress tensor”, ρ is a “mass density”, uᵢ (i=1 to 3) is a “component of a displacement vector”, nⱼ (j=1 to 3) is a “component of an outward normal vector”, Ω is a “region occupied by the volume of the resonator element”, and Γ is a “hold boundary”. In addition, the above Expression (5) is an expression when piezoelectricity and thermal elasticity are neglected. The boundary conditions of the semi-infinite medium provided virtually are applied to the third term on the left side of Expression (5), and a summation rule is applied for the suffix (i, j).

$${\int }_{Γ} {T}_{ij} {n}_{j} δ {u}_{i} d Γ \qquad ( 6 )$$

From the reason described above, the result shown in Table 1 is obtained.

### Second Embodiment

Next, a resonator according to a second embodiment of the invention will be described.

FIG. 5 is a plan view showing the resonator according to the second embodiment of the invention.

In addition, for convenience of explanation, the front side of the plane of FIG. 5 will be called “top” and the back side of the plane of FIG. 5 will be called “bottom” hereinbelow.

Hereinafter, the resonator of the second embodiment will be described focusing on the differences from the above embodiment, and explanation regarding the same matters will be omitted.

The resonator according to the second embodiment of the invention is the same as that of the first embodiment described above except that the configuration of the base portion of the resonator element is different. In addition, the same components as in the embodiment described above are denoted by the same reference numerals.

A resonator 1A shown in FIG. 5 includes a resonator element 2A and a package 9A in which the resonator element 2A is housed.

The resonator element 2A includes a quartz crystal substrate 3A (vibrating body).

The quartz crystal substrate 3A includes a base portion 4A and a pair of (two) vibrating arms 5 and 6 extending from the base portion 4A. In addition, although not shown, first and second driving electrodes for exciting the vibrating arms 5 and 6 are provided on the quartz crystal substrate 3A.

The base portion 4A includes a main body 41 connected to each of the vibrating arms 5 and 6, a fixed portion 42A fixed to the package 9, and a connecting portion 44A that connects the main body 41 and the fixed portion 42A to each other.

The connecting portion 44A extends from the main body 41 to the opposite side of the two vibrating arms 5 and 6.

The fixed portion 42A extends from the connecting portion 44A along one direction of the +X-axis direction. That is, the connecting portion 44A and the fixed portion 42A are disposed so as to form an L shape. In this case, the resonance frequency of the unnecessary vibration mode in which the vibrating arms 5 and 6 bend and vibrate in the same direction of the +X-axis direction or the −X-axis direction can be separated from the resonance frequency of the vibration mode in which the vibrating arms 5 and 6 bend and vibrate so as to be spaced apart from each other. Since it is possible to prevent the modes from being strongly coupled by ensuring 10% or preferably 20% separation as the difference between the resonance frequencies with the latter case as a reference, it is possible to reduce the vibration leakage to the package 9A from the resonator element 2A more effectively. In addition, the fixed portion 42A may extend from the connecting portion 44A along one direction of the −X-axis direction.

In addition, the bottom surface of the fixed portion 42A is a −Z′ surface of the crystal.

The package 9A in which the resonator element 2A is housed includes a base 91A and a lid 92 bonded to each other, and a storage space in which the resonator element 2A is housed is formed between the base 91A and the lid 92.

Connecting terminals 951A and 961A are formed on the top surface of the base 91A.

In addition, the resonator element 2A is fixed to the connecting terminals 951A and 961A through a conductive adhesive 11A on the bottom surface of the fixed portion 42A.

That is, in the resonator element 2A in which the vibrating arms 5 and 6 extend in the +Y′-axis direction, the principal surface of the base portion 4A on the −Z′-axis side of the crystal is fixed to the package 9A.

By the resonator 1A according to the second embodiment described above, it is also possible to reduce the vibration leakage to the package 9A from the resonator element 2A.

### Third Embodiment

Next, a resonator according to a third embodiment of the invention will be described.

FIG. 6 is a plan view showing the resonator according to the third embodiment of the invention, and FIGS. 7A and 7B are diagrams for explaining a base portion of a resonator element provided in the resonator shown in FIG. 6. In addition, FIG. 8 is a diagram for explaining a vibrating arm used in the simulation to examine the relationship between the hammerhead occupancy of the vibrating arm and a low R1 index. In addition, FIG. 9 is a diagram for explaining the width (effective width a) of a plate-shaped vibrating arm having the same Q value and natural frequency as the vibrating arm shown in FIG. 8, and FIGS. 10A and 10B are graphs showing the relationship between the hammerhead occupancy and the low R1 index.

In addition, for convenience of explanation, the front side of the plane of FIG. 6 will be called “top” and the back side of the plane of FIG. 6 will be called “bottom” hereinbelow.

Hereinafter, the resonator of the third embodiment will be described focusing on the differences from the above embodiments, and explanation regarding the same matters will be omitted.

The resonator according to the third embodiment of the invention is mainly the same as that of the first embodiment described above except that the configuration of the base portion of the resonator element, the extending direction of the vibrating arm, and the fixed surface of the base portion are different. In addition, the same components as in the embodiments described above are denoted by the same reference numerals.

A resonator 1B shown in FIG. 6 includes a resonator element 2B and a package 9B in which the resonator element 2B is housed.

The resonator element 2B includes a quartz crystal substrate 3B (vibrating body). Here, the top surface of the quartz crystal substrate 3B is a −Z′ surface of the crystal, and the bottom surface of the quartz crystal substrate 3B is a +Z′ surface of the crystal.

The quartz crystal substrate 3B includes a base portion 4B and a pair of (two) vibrating arms 5B and 6B extending from the base portion 4B. In addition, although not shown, first and second driving electrodes for vibrating the vibrating arms 5B and 6B are provided on the quartz crystal substrate 3B.

As shown in FIGS. 7A and 7B, the base portion 4B includes a main body 41B connected to each of the vibrating arms 5B and 6B.

A width-decreasing portion 45 in which the length in the X-axis direction gradually decreases as a distance from the vibrating arms 5B and 6B increases is provided in a portion of the main body 41B on the opposite side to the two vibrating arms 5B and 6B. Therefore, it is possible to reduce the vibration leakage of the resonator element 2B effectively.

This will be specifically described as follows. In addition, in order to simplify the explanation, it is assumed that the shape of the resonator element is symmetrical with respect to a predetermined axis parallel to the Y′ axis hereinafter.

First, as shown in FIG. 7A, a case where the width-decreasing portion 45 is not provided (case of a base portion 4XX) will be described.

When the vibrating arms 5B and 6B bend and deform so as to be spaced apart from each other, displacement close to the clockwise rotational movement occurs as indicated by the arrow in the main body 41B in the vicinity of which the vibrating arm 5B is connected, and displacement close to the counterclockwise rotational movement occurs as indicated by the arrow in the main body 41B in the vicinity of which the vibrating arm 6B is connected (strictly speaking, this movement cannot be said to be rotational movement; accordingly, this is expressed as “being close to the rotational movement” for convenience). Since X-axis-direction components of these displacements are in the opposite directions to each other, the X-axis-direction components are offset in the X-axis-direction middle portion of the main body 41B, and displacement in the +Y′-axis direction remains (strictly speaking, displacement in the Z′-axis direction also remains; however, the displacement in the Z′-axis direction will be omitted herein). That is, the main body 41B bends and deforms such that the X-axis-direction middle portion is displaced in the +Y′-axis direction. When an adhesive is formed in a Y′-axis-direction middle portion of the main body 41B having the above-described displacement in the +Y′-axis direction and the main body 41B is fixed to the package through the adhesive, elastic energy due to the displacement in the +Y′-axis direction leaks to the outside through the adhesive. This is the loss of vibration leakage, causing the degradation of the Q value (as a result, the CI value is degraded).

On the contrary, as shown in FIG. 7B, when the width-decreasing portion 45 is provided (case of the base portion 4B), the width-decreasing portion 45 has an arch-shaped (curved) contour. For this reason, the displacements close to the rotational movement described above are applied to each other in the width-decreasing portion 45. That is, in the X-axis-direction middle portion of the width-decreasing portion 45, displacements in the X-axis direction are offset as in the X-axis-direction middle portion of the main body 41B, and the displacement in the Y′-axis direction is also suppressed. In addition, since the contour of the width-decreasing portion 45 has an arch shape, the displacement in the +Y′-axis direction that is about to occur in the main body 41B is also suppressed. As a result, the +Y′-axis-direction displacement of the X-axis-direction middle portion of the base portion 4B becomes much smaller when the width-decreasing portion 45 is provided compared to when the width-decreasing portion 45 is not provided. That is, it is possible to obtain a resonator element having small vibration leakage.

Although the contour of the width-decreasing portion 45 has an arch shape herein, the shape of the contour of the width-decreasing portion 45 is not limited thereto as long as the operation described above can be realized. For example, it is possible to use a width-decreasing portion having a contour that is formed stepwise with a plurality of straight lines.

The vibrating arms 5B and 6B are aligned in the X-axis direction, and extend in the −Y′-axis direction from the base portion 4B so as to be parallel to each other.

In addition, the vibrating arm 53 includes a bottomed groove 55B provided on the top surface and a bottomed groove 56B provided on the bottom surface. Therefore, the vibrating arm 5B has an approximately H-shaped cross-sectional shape in a portion in which the grooves 55B and 56B are formed.

Similarly, the vibrating arm 6B includes a bottomed groove 65B provided on the top surface and a bottomed groove 66B provided on the bottom surface.

In addition, hammerheads 59B and 69B are provided at the distal ends of the vibrating arms 5B and 6B.

Here, the relationship between the total length of the vibrating arms 5B and 6B and the length and width of the hammerheads 59B and 69B will be described. In addition, since the vibrating arms 5B and 6B have the same configuration, the vibrating arm 5B will be described as a representative vibrating arm hereinafter, and explanation of the vibrating arm 6B will be omitted.

As shown in FIG. 6, assuming that the total length (length in the Y′-axis direction) of the vibrating arm 5B is L and the length (length in the Y′-axis direction) of the hammerhead 59B is H, the vibrating arm 5B satisfies the relationship of 1.2%<H/L<30.0%. If this relationship is satisfied, it is preferable that the relationship of 4.6%<H/L<22.3% be further satisfied, even though the relationship is not limited in particular. When such relationship is satisfied, the CI value of the resonator element 2B is low. Therefore, since the vibration loss is small, the resonator element 2B having excellent vibration characteristics is obtained. In addition, here, the base end of the vibrating arm 5B is set in a position of the line segment, which connects a place where one side surface is connected to the base portion 4B and a place where the other side surface is connected to the base portion 4B, in the middle of the width (length in the the X-axis direction) of the vibrating arm 5B.

In addition, assuming that the width (length in the X-axis direction) of the arm portion (portion on the proximal side from the hammerhead 59B) of the vibrating arm 5B is W1 and the width (length in the X-axis direction) of the hammerhead 59B is W2, the relationship of 1.5≦W2/W1≦10.0 is satisfied. If this relationship is satisfied, it is preferable that the relationship of 1.6≦W2/W1≦7.0 be further satisfied, even though the relationship is not limited in particular. By satisfying such relationship, it is possible to ensure the large width of the hammerhead 59B. Therefore, even if the length H of the hammerhead 59B is relatively small as described above (even if the length H of the hammerhead 59B is less than 30% of L), it is possible to sufficiently exhibit the mass effect of the hammerhead 59B. Therefore, by satisfying the relationship of 1.5≦W2/W1≦10.0, the total length L of the vibrating arm 5B is reduced. As a result, it is possible to reduce the size of the resonator element 2B.

Thus, the vibrating arm 5B satisfies the relationship of 1.2%<H/L<30.0% and the relationship of 1.5≦W2/W1≦10.0. By the synergetic effect of these two relationships, the resonator element 2B that is small and has a sufficiently reduced CI value is obtained.

Next, on the basis of a simulation result, it will be proved that the above-described effect can be exhibited by satisfying the relationship of 1.2%<H/L<30.0% and the relationship of 1.5≦W2/W1≦10.0.

This simulation was performed using one vibrating arm 5Y shown in FIG. 8.

The vibrating arm 5Y is formed of a crystal Z plate (rotation angle of 0°).

In addition, the vibrating arm 5Y extends in the −Y-axis direction, and a hammerhead 59Y is provided at the distal end.

In addition, a pair of grooves 55Y and 56Y are provided in an arm portion (portion on the proximal side from the hammerhead 59Y) of the vibrating arm 5Y so that the cross-section has an H shape.

In this simulation, as the size of the vibrating arm 5Y, as shown in FIG. 8, the total length L is 1210 μm, the thickness D is 100 μm, the width W1 of the arm portion is 98 μm, the width W2 of the hammerhead 59Y is 172 μm, the depths D1 and D2 of the grooves 55Y and 56Y are 45 μm, and the width W3 of a bank portion (sidewall of the grooves 55Y and 56Y) is 6.5 μm.

Simulation was performed while changing the length H of the hammerhead 59Y of the vibrating arm 5Y. In addition, the present inventors confirmed that a similar result to the simulation result shown below was obtained even if the size (L, W1, W2, D, D1, D2, and W3) of the vibrating arm 5Y was changed.

In this simulation, the CI value of each sample is calculated as follows. First, the Q value when only the thermoelastic loss is considered is calculated using the finite element method. Then, since the Q value is frequency-dependent, the calculated Q value is converted into the Q value at the time of 32.768 kHz (Q value after F conversion). Then, R1 (CI value) is calculated on the basis of the Q value after F conversion. Then, since the CI value is also frequency-dependent, the calculated R1 is converted into R1 at the time of 32.768 kHz and the reciprocal is taken. A result normalized with the maximum value in all simulations as 1 is assumed to be “low R1 index”. Therefore, as the low R1 index becomes close to 1 (increases), the CI value decreases.

Here, a method of converting the Q value to the Q value after F conversion is as follows.

The following calculation was performed using the following Expressions (A) and (B).

f₀=πk/(2ρCpa²) (A)

Q={ρCp/(Cα²H)}×[{1+(f/f₀)²}/(f/f₀)] (B)

In Expressions (A) and (B), π is the circumference ratio, k is the thermal conductivity of the vibrating arm 5Y in the width direction, ρ is a mass density, Cp is a heat capacity, C is an elastic stiffness constant of expansion and contraction in the length direction of the vibrating arm 5Y, α is a thermal expansion coefficient of the vibrating arm 5Y in the length direction, H is the absolute temperature, and f is a natural frequency. In addition, a is a width (effective width) when the vibrating arm 5Y is regarded as a flat plate shape shown in FIG. 9.

First, the natural frequency of the vibrating arm 5Y used in the simulation is set to F1 and the calculated Q value is set to Q1, and the value of “a” satisfying f=F1 and Q=Q1 is calculated using Expressions (A) and (B). Then, using the calculated “a” and f=32.768 kHz, the value of Q is calculated from Expression (B). The Q value obtained in this manner is the Q value after F conversion.

The result calculated as described above is shown in Table 2.

TABLE 2

| | | Natural frequency | | Q value after | | | Low R1 |
|---|---|---|---|---|---|---|---|
| | H/L | F1 [Hz] | Q1 | F conversion | R1 [Ω] | 1/R1 | index |
| SIM001 | 0.6% | 7.38E+04 | 159.398 | 76.483 | 3.50E+03 | 1.270E−04 | 0.861 |
| SIM002 | 3.3% | 5.79E+04 | 135.317 | 76.606 | 4.15E+03 | 1.363E−04 | 0.923 |
| SIM003 | 6.0% | 4.99E+04 | 120.906 | 79.442 | 4.58E+03 | 1.435E−04 | 0.972 |
| SIM004 | 8.6% | 4.48E+04 | 111.046 | 81.157 | 4.98E+03 | 1.467E−04 | 0.994 |
| SIM005 | 11.2% | 4.13E+04 | 103.743 | 82.223 | 5.37E+03 | 1.476E−04 | 1.000 |
| SIM006 | 13.9% | 3.88E+04 | 98.038 | 82.843 | 5.74E+03 | 1.471E−04 | 0.997 |
| SIM007 | 16.5% | 3.68E+04 | 93.507 | 83.225 | 6.10E+03 | 1.458E−04 | 0.988 |
| SIM008 | 19.8% | 3.49E+04 | 88.856 | 83.328 | 6.56E+03 | 1.430E−04 | 0.969 |
| SIM009 | 23.1% | 3.35E+04 | 85.017 | 83.115 | 7.02E+03 | 1.393E−04 | 0.944 |
| SIM010 | 26.4% | 3.24E+04 | 81.772 | 82.657 | 7.50E+03 | 1.348E−04 | 0.914 |
| SIM011 | 29.8% | 3.16E+04 | 78.811 | 81.824 | 8.01E+03 | 1.296E−04 | 0.878 |
| SIM012 | 33.1% | 3.09E+04 | 76.247 | 80.864 | 8.56E+03 | 1.239E−04 | 0.839 |
| SIM013 | 36.4% | 3.04E+04 | 73.813 | 79.591 | 9.17E+03 | 1.176E−04 | 0.796 |
| SIM014 | 39.7% | 3.00E+04 | 71.409 | 77.963 | 9.87E+03 | 1.106E−04 | 0.749 |
| SIM015 | 43.0% | 2.98E+04 | 69.077 | 76.078 | 1.07E+04 | 1.032E−04 | 0.699 |
| SIM016 | 46.3% | 2.96E+04 | 66.818 | 73.978 | 1.16E+04 | 9.557E−05 | 0.648 |
| SIM017 | 49.6% | 2.95E+04 | 64.449 | 71.494 | 1.27E+04 | 8.750E−05 | 0.593 |
| SIM018 | 52.9% | 2.96E+04 | 62.042 | 68.733 | 1.40E+04 | 7.928E−05 | 0.537 |
| SIM019 | 56.2% | 2.97E+04 | 59.670 | 65.800 | 1.55E+04 | 7.104E−05 | 0.481 |
| SIM020 | 59.5% | 3.00E+04 | 57.018 | 62.370 | 1.75E+04 | 6.257E−05 | 0.424 |
| SIM021 | 62.8% | 3.03E+04 | 54.502 | 58.918 | 1.98E+04 | 5.447E−05 | 0.369 |
| SIM022 | 66.1% | 3.08E+04 | 51.676 | 54.983 | 2.29E+04 | 4.640E−05 | 0.314 |
| SIM023 | 69.4% | 3.14E+04 | 48.788 | 50.857 | 2.69E+04 | 3.871E−05 | 0.262 |
| SIM024 | 72.7% | 3.23E+04 | 45.699 | 46.416 | 3.23E+04 | 3.140E−05 | 0.213 |
| SIM025 | 76.0% | 3.33E+04 | 42.398 | 41.687 | 4.00E+04 | 2.461E−05 | 0.167 |
| SIM026 | 79.3% | 3.47E+04 | 39.084 | 36.902 | 5.08E+04 | 1.857E−05 | 0.126 |
| SIM027 | 82.6% | 3.65E+04 | 35.523 | 31.872 | 6.77E+04 | 1.325E−05 | 0.090 |
| SIM028 | 85.5% | 3.86E+04 | 32.226 | 27.387 | 9.12E+04 | 9.314E−06 | 0.063 |
| SIM029 | 88.3% | 4.13E+04 | 28.763 | 22.842 | 1.31E+05 | 6.056E−06 | 0.041 |
| SIM030 | 91.1% | 4.50E+04 | 24.918 | 18.132 | 2.11E+05 | 3.448E−06 | 0.023 |
| SIM031 | 93.9% | 5.07E+04 | 21.042 | 13.614 | 4.04E+05 | 1.602E−06 | 0.011 |

In addition, FIG. 10A shows a graph in which the hammerhead occupancy (H/L) is plotted on the horizontal axis and the low R1 index is plotted on the vertical axis, and FIG. 10B shows a graph obtained by enlarging a part of FIG. 10A.

As shown in FIGS. 10A and 10B, if H/L is less than 30.0%, it is possible to increase the low R1 index compared with a case where no hammerhead is provided.

In particular, the present inventors require the resonator element 23 having the low R1 index of 0.87 or more. As can be seen from Table 2 and FIGS. 10A and 10B, the low R1 index is equal to or greater than a target of 0.87 if the relationship of 1.2%<H/L<30.0% is satisfied (SIM002 to SIM011). In particular, if the relationship of 4.6%<H/L<22.3% is satisfied (SIM003 to SIM008), the low R1 index exceeds 0.95. Therefore, it can be seen that the CI value is further reduced. From the above simulation result, it was proved that the resonator element 2B having a sufficiently reduced CI value was obtained by satisfying the relationship of 1.2%<H/L<30.0%.

In addition, by setting L≦2 μm, preferably, L 1 μm in the resonator element 2B, it is possible to obtain the small resonator element 2B used in an oscillator that is mounted in a portable music device, an IC card, and the like.

In addition, by setting W1≦100 μm, preferably, W1≦50 μm, it is also possible to obtain the resonator element 2B, which resonates at a low frequency and which is used in an oscillation circuit for realizing low power consumption, in the range of L.

In addition, in the case of an adiabatic region, it is preferable to set W1≧12.8 in the resonator element 2B in which the vibrating arms 5B and 6B extend in the Y′ direction and bend and vibrate in the X direction in the crystal Z plate. In this case, since an adiabatic region can be reliably obtained, thermoelastic loss is reduced by the formation of the grooves 55B and 65B, and the Q value is improved. In addition, due to driving in a region where the grooves 55B and 65B are formed, the electric field efficiency is high, and the driving area is secured. Accordingly, it is possible to lower the CI value.

The package 9B in which the resonator element 2B is housed includes a base 91B and a lid 92B bonded to each other, and a storage space in which the resonator element 2B is housed is formed between the base 91B and the lid 92B.

Connecting terminals 951B and 961B are formed on the top surface of the base 91B.

In addition, the resonator element 2B is fixed to the connecting terminals 951B and 961B through a conductive adhesive 11B on the bottom surface of the base portion 4B.

That is, in the resonator element 2B in which the vibrating arms 5B and 6B extend in the −Y′-axis direction, the principal surface of the base portion 4B on the +Z′-axis side of the crystal is fixed to the package 9B.

By the resonator 1B according to the third embodiment described above, it is also possible to reduce the vibration leakage to the package 9B from the resonator element 2B.

### Fourth Embodiment

Next, a resonator according to a fourth embodiment of the invention will be described.

FIG. 11 is a plan view showing the resonator according to the fourth embodiment of the invention.

In addition, for convenience of explanation, the front side of the plane of FIG. 11 will be called “top” and the back side of the plane of FIG. 11 will be called “bottom” hereinbelow.

Hereinafter, the resonator of the fourth embodiment will be described focusing on the differences from the above embodiments, and explanation regarding the same matters will be omitted.

The resonator according to the fourth embodiment of the invention is the same as that of the third embodiment described above except that the configuration of the base portion of the resonator element is different. In addition, the same components as in the embodiments described above are denoted by the same reference numerals.

A resonator 1C shown in FIG. 11 includes a resonator element 2C and a package 9C in which the resonator element 2C is housed.

The resonator element 2C includes a quartz crystal substrate 3C (vibrating body).

The quartz crystal substrate 3C includes a base portion 4C and a pair of (two) vibrating arms 5B and 6B extending from the base portion 4C.

The base portion 4C includes a main body 41C connected to each of the vibrating arms 5B and 6B, a fixed portion 42C fixed to the package 9C, and a connecting portion 44C that connects the main body 41C and the fixed portion 42C to each other.

The connecting portion 44C extends from the main body 41C toward the vibrating arms 5B and 6B between the two vibrating arms 5B and 6B. Thus, the connecting portion 44C can be disposed between the two vibrating arms 5B and 6B. Therefore, it is possible to reduce the size of the resonator element 2C and as a result, it is possible to reduce the size of the resonator 1C.

In the present embodiment, the fixed portion 42C is disposed between the two vibrating arms 5B and 6B. Accordingly, the length of the resonator element 2C in the Y′-axis direction can be reduced. As a result, it is possible to reduce the size of the resonator element 2C effectively.

The package 9C in which the resonator element 2C is housed includes abase 91C and a lid 92B bonded to each other, and a storage space in which the resonator element 2C is housed is formed between the base 91C and the lid 92B.

Connecting terminals 951C and 961C are formed on the top surface of the base 91C.

In addition, the resonator element 2C is fixed to the connecting terminals 951C and 961C through a conductive adhesive 11C on the bottom surface of the fixed portion 42C.

That is, in the resonator element 2C in which the vibrating arms 5B and 6B extend in the −Y′-axis direction, the principal surface of the base portion 4C on the +Z′-axis side of the crystal is fixed to the package 9C.

Using the resonator 1C according to the fourth embodiment described above, it is also possible to reduce the vibration leakage to the package 9C from the resonator element 2C.

### Fifth Embodiment

Next, a resonator according to a fifth embodiment of the invention will be described.

FIG. 12 is a plan view showing the resonator according to the fifth embodiment of the invention.

In addition, for convenience of explanation, the front side of the plane of FIG. 12 will be called “top” and the back side of the plane of FIG. 12 will be called “bottom” hereinbelow.

Hereinafter, the resonator of the fifth embodiment will be described focusing on the differences from the above embodiments, and explanation regarding the same matters will be omitted.

The resonator according to the fifth embodiment of the invention is the same as that of the fourth embodiment described above except that the configuration of the base portion of the resonator element is different. In addition, the same components as in the embodiments described above are denoted by the same reference numerals.

A resonator 1D shown in FIG. 12 includes a resonator element 2D and a package 9D in which the resonator element 2D is housed.

The resonator element 2D includes a quartz crystal substrate 3D (vibrating body).

The quartz crystal substrate 3D includes a base portion 4D and a pair of (two) vibrating arms 5B and 6B extending from the base portion 4D.

The base portion 4D includes a main body 41D connected to each of the vibrating arms 5B and 6B, a fixed portion 42D fixed to the package 9D, and a connecting portion 44D that connects the main body 41D and the fixed portion 42D to each other.

The connecting portion 44D extends from the main body 41D toward the vibrating arms 5B and 6B between the two vibrating arms 5B and 6B.

In the present embodiment, the fixed portion 42D is disposed on the opposite side to the main body 41D with respect to the two vibrating arms 5B and 6B. Therefore, it is possible to reduce the vibration leakage to the package 9D from the resonator element 2D more effectively.

The package 9D in which the resonator element 2D is housed includes a base 91D and a lid 92D bonded to each other, and a storage space in which the resonator element 2D is housed is formed between the base 91D and the lid 92D.

Connecting terminals 951D and 961D are formed on the top surface of the base 91D.

In addition, the resonator element 2D is fixed to the connecting terminals 951D and 961D through a conductive adhesive 11D on the bottom surface of the fixed portion 42D.

That is, in the resonator element 2D in which the vibrating arms 5B and 6B extend in the −Y′-axis direction, the principal surface of the base portion 4D on the +Z′-axis side of the crystal is fixed to the package 9D.

By the resonator 1D according to the fifth embodiment described above, it is also possible to reduce the vibration leakage to the package 9D from the resonator element 2D.

### Oscillator

Next, an oscillator to which the resonator according to the invention is applied (oscillator according to the invention) will be described.

FIG. 13 is a cross-sectional view showing an example of the oscillator according to the invention.

An oscillator 10 shown in FIG. 13 includes a resonator 1′ and an IC chip (chip component) 80 for driving the resonator element 2. Hereinafter, the oscillator 10 will be described focusing on the differences from the resonator described above, and explanation regarding the same matters will be omitted.

The package 9 includes a box-shaped base 91 having a recess 911 and a plate-shaped lid 92 for closing the opening of the recess 911.

The recess 911 of the base 91 has a first recess 911a opened on the top surface of the base 91, a second recess 911b opened in a middle portion of the bottom surface of the first recess 911a, and a third recess 911c opened in a middle portion of the bottom surface of the second recess 911b.

Connecting terminals 95 and 96 are formed on the bottom surface of the first recess 911a. In addition, the IC chip 80 is disposed on the bottom surface of the third recess 911c. The IC chip 80 includes a driving circuit (oscillation circuit) for controlling the driving of the resonator element 2. When the resonator element 2 is driven by the IC chip 80, it is possible to extract a signal of a predetermined frequency.

In addition, a plurality of internal terminals 93 electrically connected to the IC chip 80 through a wire are formed on the bottom surface of the second recess 911b. A terminal electrically connected to an external terminal (mounting terminal) 94 formed on the bottom surface of the package 9 through a via (not shown) formed in the base 91, a terminal electrically connected to the connecting terminal 95 through a via or a wire (not shown), and a terminal electrically connected to the connecting terminal 96 through a via or a wire (not shown) are included in the plurality of internal terminals 93.

In addition, although the configuration in which the IC chip 80 is disposed in the storage space has been described in the configuration shown in FIG. 13, the arrangement of the IC chip 80 is not limited in particular. For example, the IC chip 80 may be disposed outside the package 9 (disposed on the bottom surface of the base).

According to the oscillator 10, it is possible to exhibit excellent reliability.

### Electronic Apparatus

Next, an electronic apparatus to which the resonator according to the invention is applied (electronic apparatus according to the invention) will be described in detail with reference to FIGS. 14 to 17.

FIG. 14 is a perspective view showing the configuration of a mobile (or notebook) personal computer as an electronic apparatus including the resonator according to the invention. In FIG. 14, a personal computer 1100 is configured to include a main body 1104 having a keyboard 1102 and a display unit 1106 having a display section 100, and the display unit 1106 is supported so as to be rotatable with respect to the main body 1104 through a hinge structure. The resonator 1 that functions as a filter, a resonator, a reference clock, and the like is provided in the personal computer 1100.

FIG. 15 is a perspective view showing the configuration of a mobile phone (PHS is also included) as an electronic apparatus including the resonator according to the invention. In FIG. 15, a mobile phone 1200 includes a plurality of operation buttons 1202, an earpiece 1204, and a speaker 1206, and a display unit 100 is disposed between the operation buttons 1202 and the earpiece 1204. The resonator 1 that functions as a filter, a resonator, and the like is built in the mobile phone 1200.

FIG. 16 is a perspective view showing the configuration of a digital still camera as an electronic apparatus including the resonator according to the invention. In addition, connection with an external device is simply shown in FIG. 16. Here, a silver halide photograph film is exposed to light according to an optical image of a subject in a typical camera, while a digital still camera 1300 generates an imaging signal (image signal) by performing photoelectric conversion of an optical image of a subject using an imaging element, such as a charge coupled device (CCD).

A display unit is provided on the back of a case (body) 1302 in the digital still camera 1300, so that display based on the imaging signal of the CCD is performed. The display unit functions as a viewfinder that displays a subject as an electronic image. In addition, a light receiving unit 1304 including an optical lens (imaging optical system), a CCD, and the like is provided on the front side (back side in FIG. 16) of the case 1302.

When a photographer checks a subject image displayed on the display unit and presses a shutter button 1306, an imaging signal of the CCD at that point in time is transferred and stored in a memory 1308. In addition, in the digital still camera 1300, a video signal output terminal 1312 and an input/output terminal for data communication 1314 are provided on the side of the case 1302. In addition, as shown in FIG. 16, a television monitor 1430 is connected to the video signal output terminal 1312 and a personal computer 1440 is connected to the input/output terminal for data communication 1314 when necessary. In addition, an imaging signal stored in the memory 1308 may be output to the television monitor 1430 or the personal computer 1440 by a predetermined operation. The resonator 1 that functions as a filter, a resonator, and the like is built in the digital still camera 1300.

FIG. 17 is a perspective view showing the configuration of a moving object (vehicle) as an electronic apparatus including the resonator according to the invention. In FIG. 17, a moving object 1500 includes a vehicle object 1501 and four wheels 1502, and is configured to rotate the wheels 1502 using a power source (engine; not shown) provided in the vehicle object 1501. The oscillator 10 (resonator 1) is built in the moving object 1500.

According to the moving object, it is possible to exhibit excellent reliability.

In addition, the electronic apparatus including the resonator element according to the invention can be applied not only to the personal computer (mobile personal computer) shown in FIG. 14, the mobile phone shown in FIG. 15, the digital still camera shown in FIG. 16, and the moving object shown in FIG. 17 but also to an ink jet type discharge apparatus (for example, an ink jet printer), a laptop type personal computer, a television, a video camera, a video tape recorder, a car navigation apparatus, a pager, an electronic diary (electronic diary with a communication function is also included), an electronic dictionary, an electronic calculator, an electronic game machine, a word processor, a workstation, a video phone, a television monitor for security, electronic binoculars, a POS terminal, medical equipment (for example, an electronic thermometer, a sphygmomanometer, a blood sugar meter, an electrocardiographic measurement device, an ultrasonic diagnostic apparatus, and an electronic endoscope), a fish detector, various measurement apparatuses, instruments (for example, instruments for vehicles, aircraft, and ships), and a flight simulator, for example.

While the resonator, the oscillator, the electronic apparatus, and the moving object according to the invention have been described with reference to the illustrated embodiments, the invention is not limited thereto, and the configuration of each portion may be replaced with an arbitrary configuration having the same function. In addition, other arbitrary structures may be added to the invention. In addition, the embodiments described above may be appropriately combined.

In addition, for example, the resonator element can also be applied to a sensor, such as a gyro sensor, without being limited to the oscillator.

The entire disclosure of Japanese Patent Application No. 2013-0052488, filed Mar. 14, 2013 is expressly incorporated by reference herein.

What is claimed is:

1. A resonator, comprising:
a resonator element including a vibrating body formed of crystal; and
a package in which the resonator element is housed,
wherein, in a Cartesian coordinate system having an X axis as an electrical axis, a Y axis as a mechanical axis, and a Z axis as an optical axis of the quartz crystal, assuming that an axis obtained by inclining the Z axis so that a +Z side rotates in a −Y direction of the Y axis with the X axis as a rotation axis is a Z′ axis and an axis obtained by inclining the Y axis so that a +Y side rotates in a +Z direction of the Z axis with the X axis as a rotation axis is a Y′ axis, the vibrating body includes a base portion and two vibrating arms that are aligned along the X-axis direction and extend along the Y′ axis from the base portion in plan view,
a principal surface of the base portion crossing the Z′ axis is fixed to the package, and
a polarity of the Y′ axis in the extending direction of the vibrating arms is different from a polarity of the Z′ axis that is in a direction in which the principal surface fixed to the package faces.

2. The resonator according to claim 1,
wherein each of the vibrating arms extends in a positive direction of the Y′ axis, and
the principal surface of the base portion fixed to the package faces a negative side of the Z′ axis.

3. The resonator according to claim 1,
wherein each of the vibrating arms extends in a negative direction of the Y′ axis, and
the principal surface of the base portion fixed to the package faces a positive side of the Z′ axis.

4. The resonator according to claim 1,
wherein the base portion includes a main body connected to the vibrating arms, a fixed portion fixed to the package, and a connecting portion that connects the main body and the fixed portion to each other and has a smaller width than the main body.

5. The resonator according to claim 4,
wherein the connecting portion is disposed between the two vibrating arms in plan view.

6. The resonator according to claim 4,
wherein the fixed portion is disposed between the two vibrating arms in plan view.

7. The resonator according to claim 4,
wherein the fixed portion is disposed on an opposite side to the main body with respect to the vibrating arms in plan view.

8. The resonator according to claim 4,
wherein the connecting portion includes a connection portion extending from the main body to an opposite side to the vibrating arms in plan view.

9. The resonator according to claim 8,
wherein the fixed portion includes two island portions disposed so as to be spaced apart from each other along the X-axis direction,
the two vibrating arms are disposed between the two island portions, and
the connecting portion includes two branch portions that are branched from the connection portion and are connected to the two island portions.

10. The resonator according to claim 8,
wherein the fixed portion extends from the connecting portion along a positive direction of the X axis or a negative direction of the X axis.

11. The resonator according to claim 1,
wherein the base portion includes a width-decreasing portion, in which a length in the X-axis direction gradually decreases as a distance from each of the vibrating arms increases, in a portion on an opposite side to the vibrating arms.

12. An oscillator, comprising:
the resonator according to claim 1; and
an oscillation circuit electrically connected to the resonator element.

13. An oscillator, comprising:
the resonator according to claim 2; and
an oscillation circuit electrically connected to the resonator element.

14. An oscillator, comprising:
the resonator according to claim 3; and
an oscillation circuit electrically connected to the resonator element.

15. An electronic apparatus, comprising:
the resonator according to claim 1.

16. An electronic apparatus, comprising:
the resonator according to claim 2.

17. An electronic apparatus, comprising:
the resonator according to claim 3.

18. A moving object, comprising:
the resonator according to claim 1.

19. A moving object, comprising:
the resonator according to claim 2.

20. A moving object, comprising:
the resonator according to claim 3.
